(19) United States
(12) Patent Application Publication
(10) Pub. No.: US 2024/0324180 A1
(43) Pub. Date: Sep. 26, 2024

(54) SEMICONDUCTOR DEVICE AND SEMICONDUCTOR MEMORY DEVICE

(71) Applicant: Kioxia Corporation, Tokyo (JP)

(72) Inventors: Ken SHIMOMORI, Yokkaichi (JP); Takuya KIKUCHI, Yokkaichi (JP); Ryosuke YAMAMOTO, Nagoya (JP)

(73) Assignee: Kioxia Corporation, Tokyo (JP)

(21) Appl. No.: 18/609,019

(22) Filed: Mar. 19, 2024

(30) Foreign Application Priority Data
Mar. 24, 2023 (JP) 2023-047522

(51) Int. Cl. H10B 12/00

(52) U.S. Cl. CPC H10B 12/33; H10B 12/05

(57) ABSTRACT

A semiconductor device of embodiments includes: a first electrode; a second electrode; an oxide semiconductor layer between the electrodes; a gate electrode surrounding the oxide semiconductor layer; a gate insulating layer between the gate electrode and the oxide semiconductor layer and spaced from the first electrode; a first insulating layer between the first electrode and the gate electrode, the gate insulating layer between the first insulating layer and the oxide semiconductor layer; and an intermediate layer between the first electrode and the first insulating layer, including a first region and a second region between the first region and the first insulating layer. The first region contains a first metal element and oxygen, the second region contains a second metal element, and an oxygen concentration in the second region is lower than that in the first region.

### CROSS-REFERENCE TO RELATED APPLICATION

This application is based upon and claims the benefit of priority from Japanese Patent Application No. 2023-047522, filed on Mar. 24, 2023, the entire contents of which are incorporated herein by reference.

### FIELD

Embodiments described herein relate generally to a semiconductor device and a semiconductor memory device.

### BACKGROUND

An oxide semiconductor transistor in which a channel is formed in an oxide semiconductor layer has an excellent characteristic that the channel leakage current during off operation is very small. For this reason, for example, the oxide semiconductor transistor can be applied as a switching transistor of a memory cell in a dynamic random access memory (DRAM).

### BRIEF DESCRIPTION OF THE DRAWINGS

FIG. 1 is a schematic cross-sectional view of a semiconductor device according to a first embodiment;

FIG. 2 is a schematic cross-sectional view of the semiconductor device according to the first embodiment;

FIG. 3 is a schematic cross-sectional view of the semiconductor device according to the first embodiment;

FIG. 4 is a schematic cross-sectional view of the semiconductor device according to the first embodiment;

FIG. 5 is a schematic cross-sectional view showing an example of a method for manufacturing the semiconductor device according to the first embodiment;

FIG. 6 is a schematic cross-sectional view showing an example of the method for manufacturing the semiconductor device according to the first embodiment;

FIG. 7 is a schematic cross-sectional view showing an example of the method for manufacturing the semiconductor device according to the first embodiment;

FIG. 8 is a schematic cross-sectional view showing an example of the method for manufacturing the semiconductor device according to the first embodiment;

FIG. 9 is a schematic cross-sectional view showing an example of the method for manufacturing the semiconductor device according to the first embodiment;

FIG. 10 is a schematic cross-sectional view showing an example of the method for manufacturing the semiconductor device according to the first embodiment;

FIG. 11 is a schematic cross-sectional view showing an example of the method for manufacturing the semiconductor device according to the first embodiment;

FIG. 12 is a schematic cross-sectional view showing an example of the method for manufacturing the semiconductor device according to the first embodiment;

FIG. 13 is a schematic cross-sectional view of a semiconductor device according to a comparative example;

FIG. 14 is a schematic cross-sectional view showing an example of a method for manufacturing the semiconductor device according to the comparative example;

FIG. 15 is a schematic cross-sectional view showing an example of the method for manufacturing the semiconductor device according to the comparative example;

FIG. 16 is a schematic cross-sectional view showing an example of the method for manufacturing the semiconductor device according to the comparative example;

FIG. 17 is a schematic cross-sectional view showing an example of the method for manufacturing the semiconductor device according to the comparative example;

FIG. 18 is a schematic cross-sectional view showing an example of the method for manufacturing the semiconductor device according to the comparative example;

FIG. 19 is a schematic cross-sectional view showing an example of the method for manufacturing the semiconductor device according to the comparative example;

FIG. 20 is a schematic cross-sectional view showing an example of the method for manufacturing the semiconductor device according to the comparative example;

FIG. 21 is a schematic cross-sectional view of a semiconductor device according to a modification example of the first embodiment;

FIG. 22 is a schematic cross-sectional view of a semiconductor device according to a second embodiment;

FIG. 23 is a schematic cross-sectional view of a semiconductor device according to a modification example of the second embodiment;

FIG. 24 is a schematic cross-sectional view of a semiconductor device according to a third embodiment;

FIG. 25 is an equivalent circuit diagram of a semiconductor memory device according to a fourth embodiment; and

FIG. 26 is a schematic cross-sectional view of the semiconductor memory device according to the fourth embodiment.

### DETAILED DESCRIPTION

A semiconductor device of embodiments includes: a first electrode; a second electrode; an oxide semiconductor layer provided between the first electrode and the second electrode; a gate electrode surrounding the oxide semiconductor layer; a gate insulating layer provided between the gate electrode and the oxide semiconductor layer and spaced from the first electrode; a first insulating layer provided between the first electrode and the gate electrode, the gate insulating layer being provided between the first insulating layer and the oxide semiconductor layer; and an intermediate layer provided between the first electrode and the first insulating layer, including a first region and a second region provided between the first region and the first insulating layer, and having a different chemical composition from the first electrode. The first region contains a first metal element and oxygen (O), the second region contains a second metal element, and an oxygen concentration in the second region is lower than an oxygen concentration in the first region.

Hereinafter, embodiments will be described with reference to the diagrams. In addition, in the following description, the same or similar members and the like are denoted by the same reference numerals, and the description of the members and the like once described may be omitted as appropriate.

In addition, in this specification, the terms “on”, “below”, “upper”, and “lower” may be used for convenience. “On”, “below”, “upper”, and “lower” are terms that only indicate the relative positional relationship in the diagrams, but are not terms that define the positional relationship with respect to gravity.

The qualitative analysis and quantitative analysis of the chemical composition of members forming the semiconductor device and the semiconductor memory device in this specification can be performed by, for example, secondary ion mass spectrometry (SIMS), energy dispersive X-ray spectroscopy (EDX), and Rutherford back-scattering spectroscopy (RBS). In addition, when measuring the thickness of each member forming the semiconductor device and the semiconductor memory device, a distance between members, a crystal particle size, and the like, it is possible to use, for example, a transmission electron microscope (TEM). In addition, for the identification of the constituent materials of members forming the semiconductor device and the semiconductor memory device and the measurement of the abundance ratio of the constituent materials, for example, X-ray photoelectron spectroscopy (XPS), hard X-ray photoelectron spectroscopy (HAXPES), and electron energy loss spectroscopy (EELS) can be used.

In this specification, “metal” is a general term for substances that exhibit metallic properties, and for example, metal compounds such as metal nitrides and metal carbides that exhibit metallic properties are also included in the scope of “metal”.

### First Embodiment

A semiconductor device according to a first embodiment includes: a first electrode; a second electrode; an oxide semiconductor layer provided between the first electrode and the second electrode; a gate electrode surrounding the oxide semiconductor layer; a gate insulating layer provided between the gate electrode and the oxide semiconductor layer and spaced from the first electrode; a first insulating layer provided between the first electrode and the gate electrode, the gate insulating layer being provided between the first insulating layer and the oxide semiconductor layer; and an intermediate layer provided between the first electrode and the first insulating layer, including a first region and a second region provided between the first region and the first insulating layer, and having a different chemical composition from the first electrode. The first region contains a first metal element and oxygen (O), the second region contains a second metal element, and an oxygen concentration in the second region is lower than an oxygen concentration in the first region.

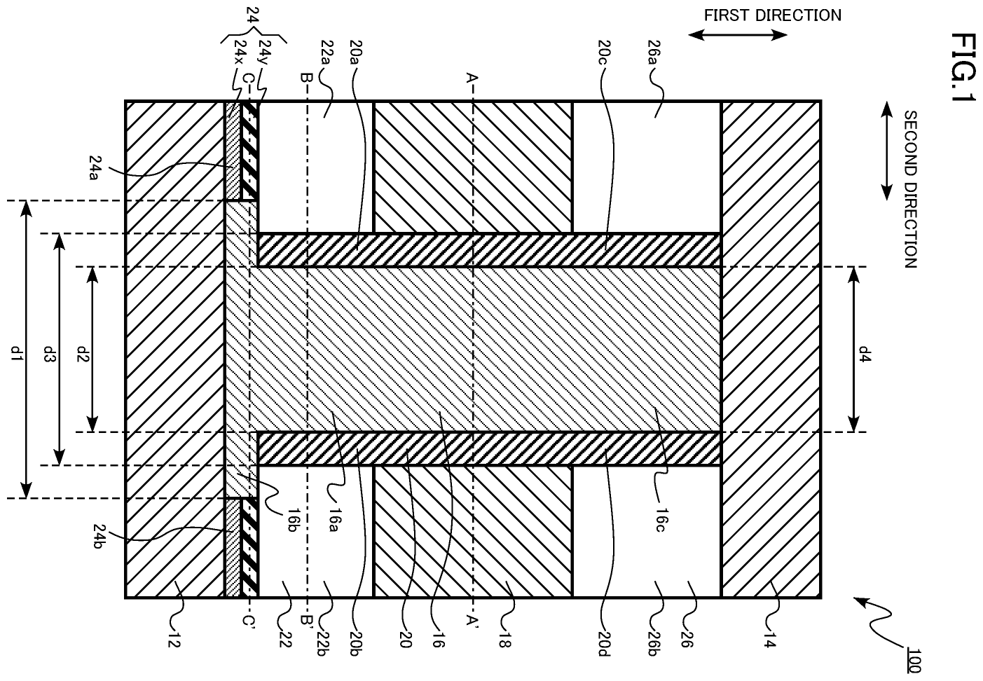

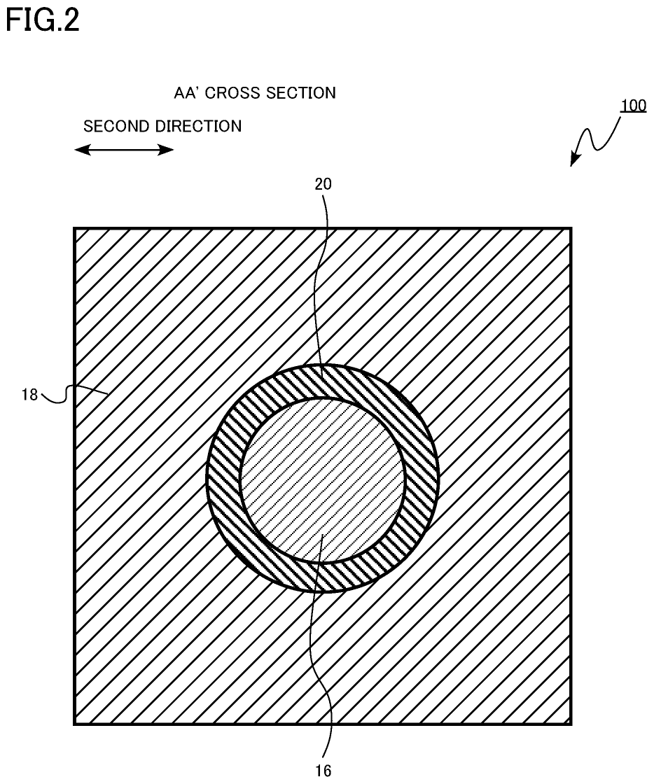

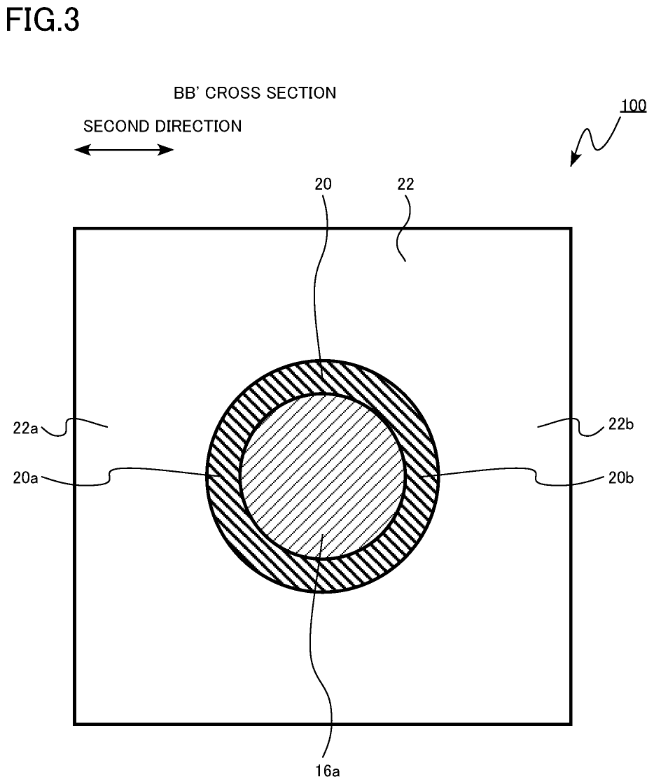

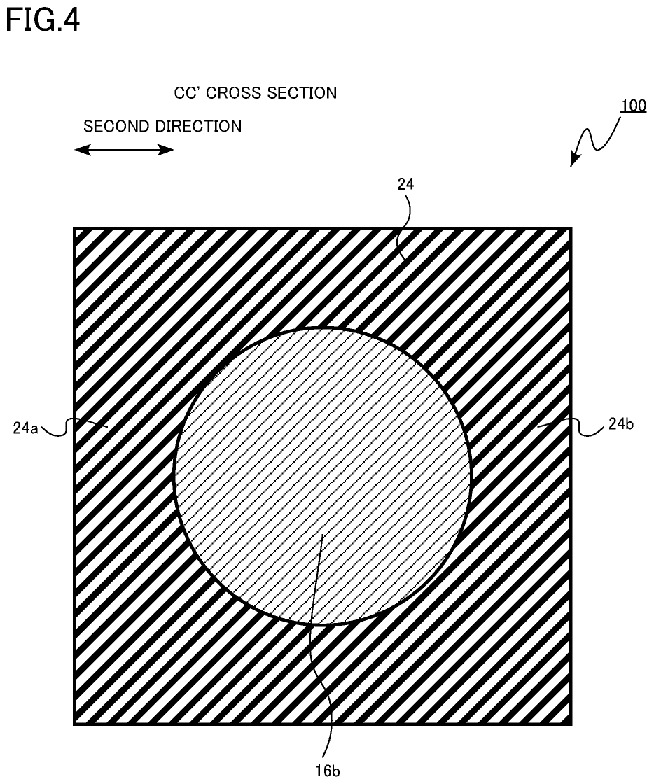

FIGS. 1 to 4 are schematic cross-sectional views of the semiconductor device according to the first embodiment. FIG. 2 is a cross-sectional view taken along the line AA′ of FIG. 1. FIG. 3 is a cross-sectional view taken along the line BB′ of FIG. 1. FIG. 4 is a cross-sectional view taken along the line CC′ of FIG. 1. In FIG. 1, the vertical direction is referred to as a first direction. In FIG. 1, the horizontal direction is referred to as a second direction. The second direction is perpendicular to the first direction.

The semiconductor device according to the first embodiment is a transistor 100. The transistor 100 is an oxide semiconductor transistor in which a channel is formed in an oxide semiconductor. In the transistor 100, a gate electrode is provided so as to surround an oxide semiconductor layer in which a channel is formed. The transistor 100 is a so-called surrounding gate transistor (SGT). The transistor 100 is a so-called vertical transistor.

The transistor 100 includes a lower electrode 12, an upper electrode 14, an oxide semiconductor layer 16, a gate electrode 18, a gate insulating layer 20, a lower insulating layer 22, a protective layer 24, and an upper insulating layer 26. The oxide semiconductor layer 16 includes a first sub-region 16a, a second sub-region 16b, and a third sub-region 16c. The lower insulating layer 22 includes a first portion 22a and a second portion 22b. The protective layer 24 includes a metal oxide region 24x and a metal region 24y. The protective layer 24 includes a third portion 24a and a fourth portion 24b. The gate insulating layer 20 includes a fifth portion 20a, a sixth portion 20b, a ninth portion 20c, and a tenth portion 20d. The upper insulating layer 26 includes a seventh portion 26a and an eighth portion 26b.

The lower electrode 12 is an example of the first electrode. The upper electrode 14 is an example of the second electrode. The first sub-region 16a is an example of a part. The second sub-region 16b is an example of another part. The lower insulating layer 22 is an example of the first insulating layer. The protective layer 24 is an example of an intermediate layer. The metal oxide region 24x is an example of the first region. The metal region 24y is an example of the second region. The upper insulating layer 26 is an example of the second insulating layer.

The lower electrode 12 is provided below the oxide semiconductor layer 16. The lower electrode 12 is electrically connected to the oxide semiconductor layer 16. The lower electrode 12 is in contact with, for example, the oxide semiconductor layer 16. The lower electrode 12 functions as a source electrode or a drain electrode of the transistor 100.

The lower electrode 12 is a conductor. The lower electrode 12 includes, for example, an oxide conductor. The lower electrode 12 is, for example, an oxide conductor layer.

The lower electrode 12 contains, for example, indium (In), tin (Sn), and oxygen (O). The lower electrode 12 contains, for example, indium tin oxide. The lower electrode 12 is, for example, an indium tin oxide layer.

The lower electrode 12 contains, for example, tin (Sn) and oxygen (O). The lower electrode 12 contains, for example, tin oxide. The lower electrode 12 is, for example, a tin oxide layer.

The lower electrode 12 contains, for example, metal. The lower electrode 12 is, for example, a metal layer.

The lower electrode 12 contains, for example, tungsten (W), molybdenum (Mo), copper (Cu), aluminum (Al), titanium (Ti), or tantalum (Ta). The lower electrode 12 is, for example, a tungsten layer, a molybdenum layer, a copper layer, an aluminum layer, a titanium layer, or a tantalum layer.

The lower electrode 12 may have, for example, a stacked structure of a plurality of conductors. The lower electrode 12 has, for example, a stacked structure of an oxide conductor layer and a metal layer. For example, the surface of the lower electrode 12 on the oxide semiconductor layer 16 side is an oxide conductor layer.

The upper electrode 14 is provided on the oxide semiconductor layer 16. The upper electrode 14 is electrically connected to the oxide semiconductor layer 16. The upper electrode 14 is in contact with, for example, the oxide semiconductor layer 16. The upper electrode 14 functions as a source electrode or a drain electrode of the transistor 100.

The upper electrode 14 is a conductor. The upper electrode 14 includes, for example, an oxide conductor. The upper electrode 14 is, for example, an oxide conductor layer.

The upper electrode 14 contains, for example, indium (In), tin (Sn), and oxygen (O). The upper electrode 14 contains, for example, indium tin oxide. The upper electrode 14 is, for example, an indium tin oxide layer.

The upper electrode 14 contains, for example, tin (Sn) and oxygen (O). The upper electrode 14 contains, for example, tin oxide. The upper electrode 14 is, for example, a tin oxide layer.

The upper electrode 14 contains, for example, metal. The upper electrode 14 is, for example, a metal layer.

The upper electrode 14 contains, for example, tungsten (W), molybdenum (Mo), copper (Cu), aluminum (Al), titanium (Ti), or tantalum (Ta). The upper electrode 14 is, for example, a tungsten layer, a molybdenum layer, a copper layer, an aluminum layer, a titanium layer, or a tantalum layer.

The upper electrode 14 may have, for example, a stacked structure of a plurality of conductors. The upper electrode 14 has, for example, a stacked structure of an oxide conductor layer and a metal layer. For example, the surface of the upper electrode 14 on the oxide semiconductor layer 16 side is an oxide conductor layer.

The lower electrode 12 and the upper electrode 14 are formed of, for example, the same material. The lower electrode 12 and the upper electrode 14 are, for example, oxide conductors containing indium (In), tin (Sn), and oxygen (O). The lower electrode 12 and the upper electrode 14 contain, for example, indium tin oxide. The lower electrode 12 and the upper electrode 14 are, for example, indium tin oxide layers.

The oxide semiconductor layer 16 is provided between the lower electrode 12 and the upper electrode 14. The oxide semiconductor layer 16 is in contact with, for example, the lower electrode 12. The oxide semiconductor layer 16 is in contact with, for example, the upper electrode 14.

The oxide semiconductor layer 16 includes the first sub-region 16a, the second sub-region 16b, and the third sub-region 16c. The first sub-region 16a is provided between the second sub-region 16b and the third sub-region 16c.

A channel that becomes a current path is formed in the oxide semiconductor layer 16 when the transistor 100 is turned on.

The oxide semiconductor layer 16 is an oxide semiconductor. The oxide semiconductor layer 16 is, for example, amorphous.

The oxide semiconductor layer 16 contains, for example, zinc (Zn), oxygen (O), and at least one element selected from a group consisting of indium (In), gallium (Ga), silicon (Si), aluminum (Al), and tin (Sn). The oxide semiconductor layer 16 contains, for example, indium (In), gallium (Ga), zinc (Zn), and oxygen (O). The oxide semiconductor layer 16 contains, for example, indium gallium zinc oxide. The oxide semiconductor layer 16 is, for example, an indium gallium zinc oxide layer.

The oxide semiconductor layer 16 contains, for example, oxygen (O) and at least one element selected from a group consisting of titanium (Ti), zinc (Zn), and tungsten (W). The oxide semiconductor layer 16 contains, for example, titanium oxide, zinc oxide, or tungsten oxide. The oxide semiconductor layer 16 is, for example, a titanium oxide layer, a zinc oxide layer, or a tungsten oxide layer.

The oxide semiconductor layer 16 has a different chemical composition from the lower electrode 12 and the upper electrode 14, for example.

The oxide semiconductor layer 16 includes oxygen vacancies. The oxygen vacancies in the oxide semiconductor layer 16 function as donors.

The length of the oxide semiconductor layer 16 in the first direction is, for example, equal to or more than 80 nm and equal to or less than 200 nm. The length of the oxide semiconductor layer 16 in the second direction is, for example, equal to or more than 20 nm and equal to or less than 100 nm.

The first direction is a direction from the lower electrode 12 toward the upper electrode 14. The second direction is a direction perpendicular to the first direction.

The gate electrode 18 faces the oxide semiconductor layer 16. The gate electrode 18 is provided so that the position coordinates of the gate electrode 18 in the first direction are a value between the position coordinates of the lower electrode 12 and the position coordinates of the upper electrode 14 in the first direction.

As shown in FIG. 2, the gate electrode 18 is provided so as to surround the oxide semiconductor layer 16. The gate electrode 18 is provided around the oxide semiconductor layer 16.

The gate electrode 18 is a conductor. The gate electrode 18 is, for example, a metal, a metal compound, or a semiconductor. The gate electrode 18 contains, for example, tungsten (W).

The length of the gate electrode 18 in the first direction is, for example, equal to or more than 20 nm and equal to or less than 100 nm.

The gate insulating layer 20 is provided between the oxide semiconductor layer 16 and the gate electrode 18. The gate insulating layer 20 is provided so as to surround the oxide semiconductor layer 16. The gate insulating layer 20 is provided between the lower electrode 12 and the upper electrode 14.

The gate insulating layer 20 is spaced from the lower electrode 12. The gate insulating layer 20 is spaced from the lower electrode 12 in the first direction. The gate insulating layer 20 is in contact with, for example, the upper electrode 14.

The gate insulating layer 20 is, for example, an oxide, a nitride, or an oxynitride. The gate insulating layer 20 contains, for example, silicon oxide, aluminum oxide, silicon nitride, aluminum nitride, or silicon oxynitride. The gate insulating layer 20 is, for example, a silicon oxide layer, an aluminum oxide layer, a silicon nitride layer, an aluminum nitride layer, or a silicon oxynitride layer.

The gate insulating layer 20 may have, for example, a stacked structure. The gate insulating layer 20 has, for example, a stacked structure of nitride and oxide. The gate insulating layer 20 has, for example, a stacked structure of a silicon nitride layer and a silicon oxide layer. The thickness of the gate insulating layer 20 is, for example, equal to or more than 2 nm and equal to or less than 10 nm.

The lower insulating layer 22 is provided on the lower electrode 12. The lower insulating layer 22 is provided between the lower electrode 12 and the gate electrode 18.

As shown in FIG. 3, the lower insulating layer 22 surrounds the first sub-region 16a of the oxide semiconductor layer 16. The lower insulating layer 22 surrounds the gate insulating layer 20. The gate insulating layer 20 is provided between the lower insulating layer 22 and the first sub-region 16a of the oxide semiconductor layer 16.

The lower insulating layer 22 is an insulator. The lower insulating layer 22 is, for example, an oxide, a nitride, or an oxynitride. The lower insulating layer 22 contains, for example, silicon (Si) and oxygen (O). The lower insulating layer 22 contains, for example, silicon oxide. The lower insulating layer 22 is, for example, a silicon oxide layer.

The protective layer 24 is provided on the lower electrode 12. The protective layer 24 is provided between the lower electrode 12 and the lower insulating layer 22. The protective layer 24 is in contact with, for example, the lower electrode 12. The protective layer 24 is in contact with, for example, the lower insulating layer 22.

As shown in FIG. 4, the protective layer 24 surrounds the second sub-region 16b of the oxide semiconductor layer 16. The protective layer 24 is in contact with, for example, the second sub-region 16b of the oxide semiconductor layer 16.

The protective layer 24 has a function of suppressing etching of the lower electrode 12 when forming a contact structure between the lower electrode 12 and the oxide semiconductor layer 16.

The protective layer 24 has a different chemical composition from the lower electrode 12, the lower insulating layer 22, and the oxide semiconductor layer 16.

The protective layer 24 includes the metal oxide region 24x and the metal region 24y. The metal region 24y is provided between the metal oxide region 24x and the lower insulating layer 22. The metal oxide region 24x is in contact with, for example, the lower electrode 12. The metal region 24y is in contact with, for example, the lower insulating layer 22. The metal oxide region 24x is in contact with, for example, the metal region 24y.

The metal oxide region 24x contains a first metal element and oxygen (O). The first metal element is, for example, at least one metal element selected from a group consisting of titanium (Ti), tungsten (W), tantalum (Ta), and molybdenum (Mo).

The metal oxide region 24x contains, for example, a metal oxide of the first metal element. The metal oxide region 24x contains, for example, at least one metal oxide selected from a group consisting of titanium oxide, tungsten oxide, tantalum oxide, and molybdenum oxide. The metal oxide region 24x is, for example, a metal oxide. The metal oxide region 24x is, for example, a titanium oxide, a tungsten oxide, a tantalum oxide, or a molybdenum oxide.

The metal region 24y contains a second metal element. The metal region 24y may or may not contain oxygen (O). The oxygen concentration in the metal region 24y is lower than the oxygen concentration in the metal oxide region 24x.

The second metal element is, for example, at least one metal element selected from a group consisting of titanium (Ti), tungsten (W), tantalum (Ta), and molybdenum (Mo).

The metal region 24y contains, for example, metal containing a first metal element. The metal region 24y contains, for example, elemental metal of the first metal element. The metal region 24y contains, for example, metal nitride of the first metal element. The metal region 24y contains, for example, metal carbide of the first metal element. The metal region 24y contains, for example, an alloy of the first metal element and another metal element. The metal region 24y is, for example, a metal.

The metal region 24y contains, for example, at least one metal selected from a group consisting of titanium, titanium nitride, titanium oxynitride, titanium carbide, tungsten, tungsten nitride, tungsten oxynitride, tungsten carbide, tantalum, tantalum nitride, tantalum oxynitride, tantalum carbide, molybdenum, molybdenum nitride, molybdenum oxynitride, molybdenum carbide, titanium tungsten, molybdenum tungsten, and tantalum tungsten.

The metal region 24y is, for example, titanium, titanium nitride, titanium oxynitride, titanium carbide, tungsten, tungsten nitride, tungsten oxynitride, tungsten carbide, tantalum, tantalum nitride, tantalum oxynitride, tantalum carbide, molybdenum, molybdenum nitride, molybdenum oxynitride, molybdenum carbide, titanium tungsten, molybdenum tungsten, or tantalum tungsten.

The first metal element contained in the metal oxide region 24x and the second metal element contained in the metal region 24y are, for example, the same element.

The thickness of the protective layer 24 in the first direction is, for example, smaller than the thickness of the lower insulating layer 22 in the first direction. The thickness of the protective layer 24 in the first direction is, for example, equal to or less than 30% of the thickness of the lower insulating layer 22 in the first direction.

The upper insulating layer 26 is provided on the gate electrode 18. The upper insulating layer 26 is provided, for example, between the gate electrode 18 and the upper electrode 14.

The upper insulating layer 26 surrounds the third sub-region 16c of the oxide semiconductor layer 16. The upper insulating layer 26 surrounds the gate insulating layer 20. The gate insulating layer 20 is provided between the upper insulating layer 26 and the third sub-region 16c of the oxide semiconductor layer 16.

The upper insulating layer 26 is an insulator. The upper insulating layer 26 is, for example, an oxide, a nitride, or an oxynitride. The upper insulating layer 26 contains, for example, silicon (Si) and oxygen (O). The upper insulating layer 26 contains, for example, silicon oxide. The upper insulating layer 26 is, for example, a silicon oxide layer.

A cross section parallel to the first direction from the lower electrode 12 to the upper electrode 14 and including the oxide semiconductor layer 16, the lower insulating layer 22, the protective layer 24, the upper insulating layer 26, and the gate insulating layer 20 is defined as a first cross section. The cross section shown in FIG. 1 is an example of the first cross section.

In the first cross section, the lower insulating layer 22 includes the first portion 22a and the second portion 22b. In addition, the protective layer 24 includes the third portion 24a and the fourth portion 24b. In addition, the gate insulating layer 20 includes the fifth portion 20a, the sixth portion 20b, the ninth portion 20c, and the tenth portion 20d. In addition, the upper insulating layer 26 includes the seventh portion 26a and the eighth portion 26b.

The oxide semiconductor layer 16 is provided between the first portion 22a and the second portion 22b. In addition, the oxide semiconductor layer 16 is provided between the third portion 24a and the fourth portion 24b.

The fifth portion 20a is provided between the first portion 22a and the oxide semiconductor layer 16. In addition, the sixth portion 20b is provided between the second portion 22b and the oxide semiconductor layer 16.

The oxide semiconductor layer 16 is provided between the seventh portion 26a and the eighth portion 26b. In addition, the ninth portion 20c is provided between the seventh portion 26a and the oxide semiconductor layer 16. In addition, the tenth portion 20d is provided between the eighth portion 26b and the oxide semiconductor layer 16.

For example, a first minimum distance (d1 in FIG. 1) between the third portion 24a and the fourth portion 24b is larger than a second minimum distance (d2 in FIG. 1) between the fifth portion 20a and the sixth portion 20b. In addition, for example, the first minimum distance d1 is larger than a third minimum distance (d3 in FIG. 1) between the first portion 22a and the second portion 22b. In addition, for example, the first minimum distance d1 is larger than a maximum distance (d4 in FIG. 1) between the ninth portion 20c and the tenth portion 20d.

Next, an example of a method for manufacturing the semiconductor device according to the first embodiment will be described.

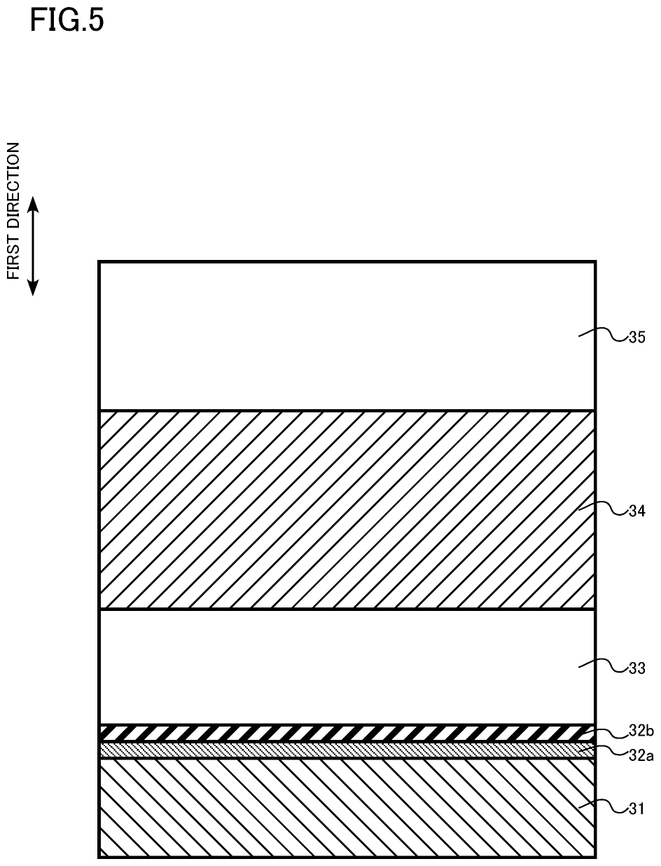

FIGS. 5 to 12 are schematic cross-sectional views showing an example of the method for manufacturing the semiconductor device according to the first embodiment. FIGS. 5 to 12 each show a cross section corresponding to FIG. 1. FIGS. 5 to 12 are diagrams showing an example of a method for manufacturing the transistor 100.

Hereinafter, a case where the lower electrode 12 is an indium tin oxide layer, the upper electrode 14 is an indium tin oxide layer, the oxide semiconductor layer 16 is an indium gallium zinc oxide layer, the gate electrode 18 is a tungsten layer, the gate insulating layer 20 is a silicon oxide layer, the lower insulating layer 22 is a silicon oxide layer, the metal oxide region 24x of the protective layer 24 is a titanium oxide, the metal oxide region 24x of the protective layer 24 is a titanium nitride, and the upper insulating layer 26 is a silicon oxide layer will be described as an example.

First, a first indium tin oxide film 31, a titanium oxide film 32a, a titanium nitride film 32b, a first silicon oxide film 33, a tungsten film 34, and a second silicon oxide film 35 are stacked in this order on a substrate (not shown) in the first direction (FIG. 5). The first indium tin oxide film 31, the titanium oxide film 32a, the titanium nitride film 32b, the first silicon oxide film 33, the tungsten film 34, and the second silicon oxide film 35 are formed by using, for example, a chemical vapor deposition method (CVD method).

A part of the first indium tin oxide film 31 finally becomes the lower electrode 12. A part of the titanium oxide film 32a finally becomes the metal oxide region 24x of the protective layer 24. A part of the titanium nitride film 32b finally becomes the metal region 24y of the protective layer 24. A part of the first silicon oxide film 33 finally becomes the lower insulating layer 22. A part of the tungsten film 34 finally becomes the gate electrode 18. A part of the second silicon oxide film 35 finally becomes the upper insulating layer 26.

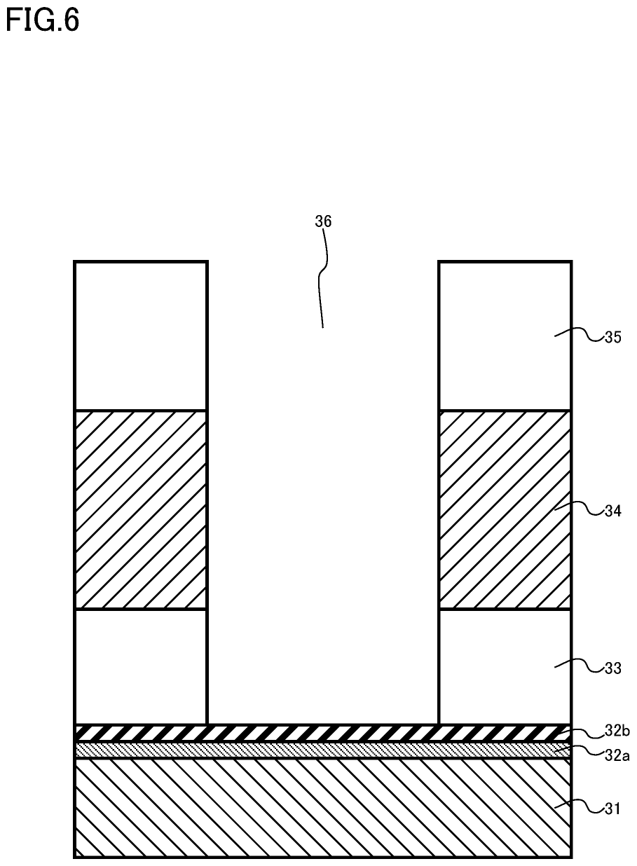

Then, an opening 36 that passes through the tungsten film 34 and the first silicon oxide film 33 and reaches the titanium nitride film 32b is formed from the surface of the second silicon oxide film 35 (FIG. 6). The opening 36 is formed by using, for example, a lithography method and a reactive ion etching method (RIE method). The RIE method is anisotropic etching using the impact of ions perpendicular to the substrate.

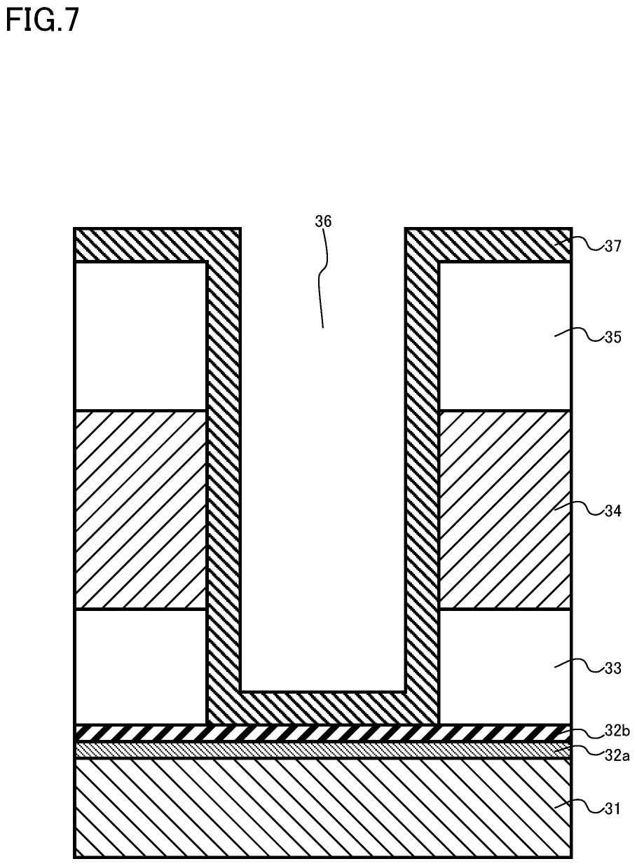

Then, a third silicon oxide film 37 is formed inside the opening 36 (FIG. 7). The third silicon oxide film 37 is formed by using, for example, a CVD method. A part of the third silicon oxide film 37 finally becomes the gate insulating layer 20.

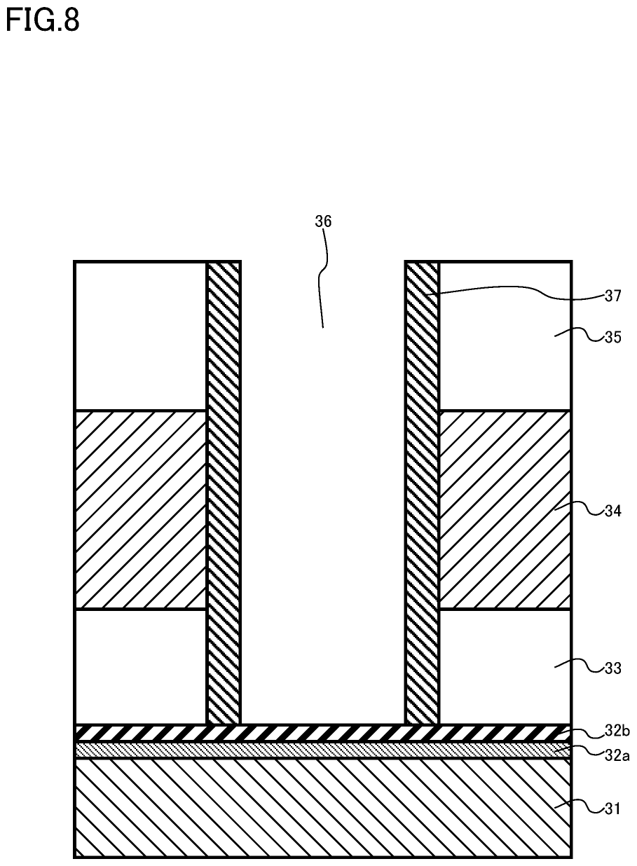

Then, the third silicon oxide film 37 at the bottom of the opening 36 is etched to expose the titanium nitride film 32b (FIG. 8). The third silicon oxide film 37 is etched by using, for example, an RIE method. For example, when etching the third silicon oxide film 37, conditions are selected such that the etching rate of the titanium nitride film 32b is lower than the etching rate of the third silicon oxide film 37.

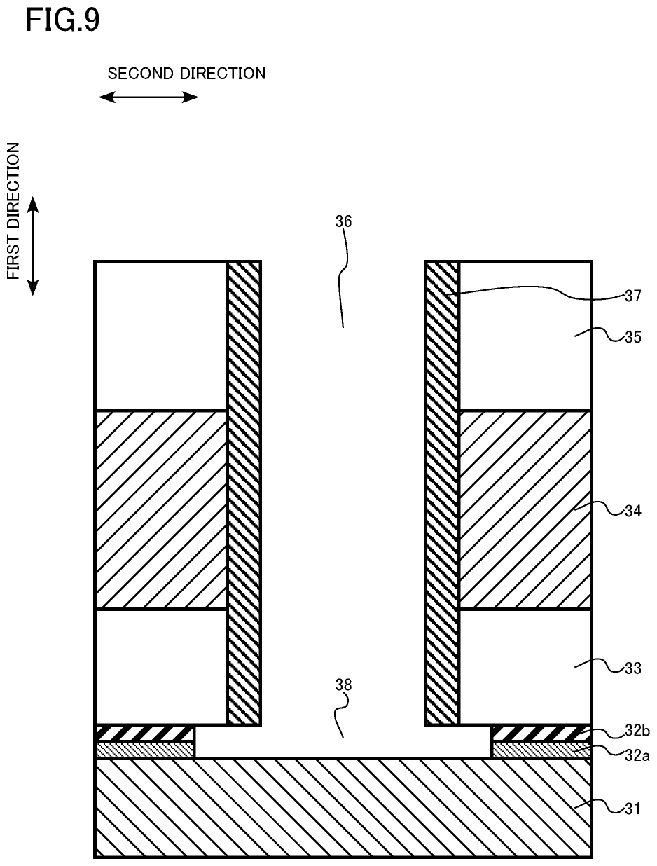

Then, the titanium nitride film 32b and the titanium oxide film 32a exposed at the bottom of the opening 36 are etched to form a recess 38 that extends in the second direction perpendicular to the first direction (FIG. 9). At the bottom of the recess 38, the first indium tin oxide film 31 is exposed.

When forming the recess 38, for example, isotropic etching is performed. When forming the recess 38, for example, the titanium nitride film 32b and the titanium oxide film 32a are etched isotropically. For example, when forming the recess 38, conditions are selected such that the etching rate of the first indium tin oxide film 31, the first silicon oxide film 33, and the third silicon oxide film 37 is lower than the etching rate of the titanium nitride film 32b and the titanium oxide film 32a.

The titanium nitride film 32b and the titanium oxide film 32a are etched by using, for example, a wet etching method. For etching the titanium nitride film 32b and the titanium oxide film 32a, for example, a solution containing hydrogen peroxide (H₂O₂) as a main component is used.

For etching the titanium nitride film 32b and the titanium oxide film 32a, for example, isotropic dry etching can also be used.

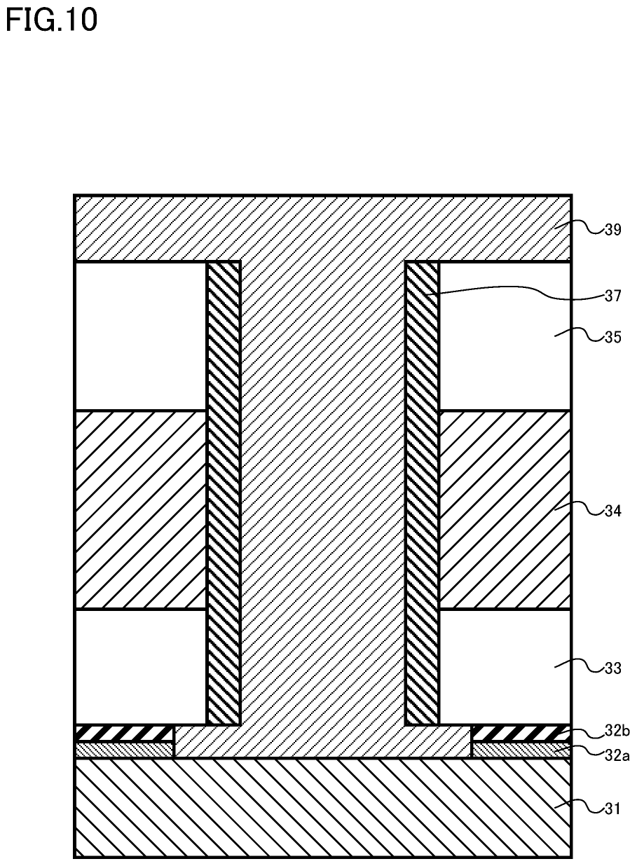

Then, an indium gallium zinc oxide film 39 is buried in the recess 38 and the opening 36 (FIG. 10). A part of the indium gallium zinc oxide film 39 finally becomes the oxide semiconductor layer 16. The indium gallium zinc oxide film 39 is formed by using, for example, a CVD method.

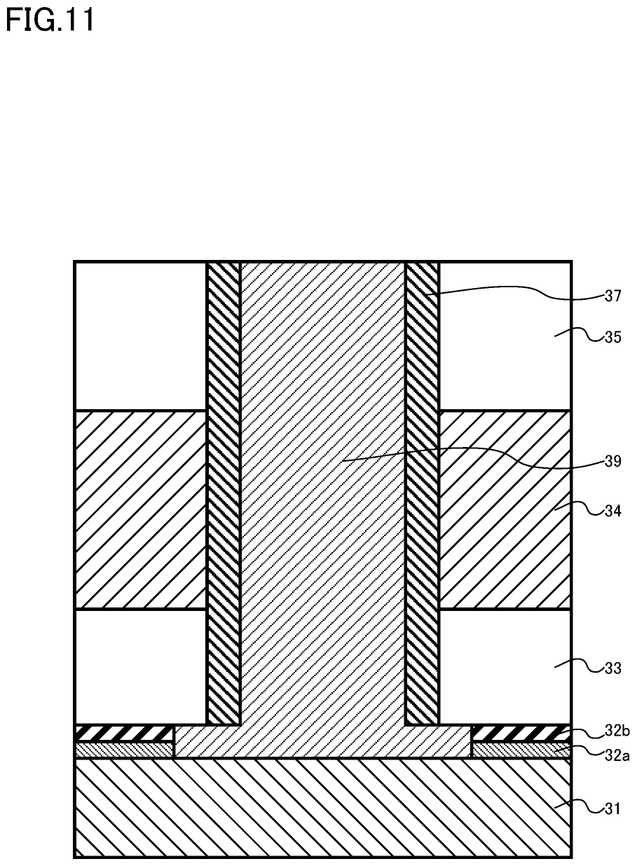

Then, an upper portion of the indium gallium zinc oxide film 39 is removed to expose the surface of the second silicon oxide film 35 (FIG. 11). For example, the indium gallium zinc oxide film 39 is removed by etching using an RIE method.

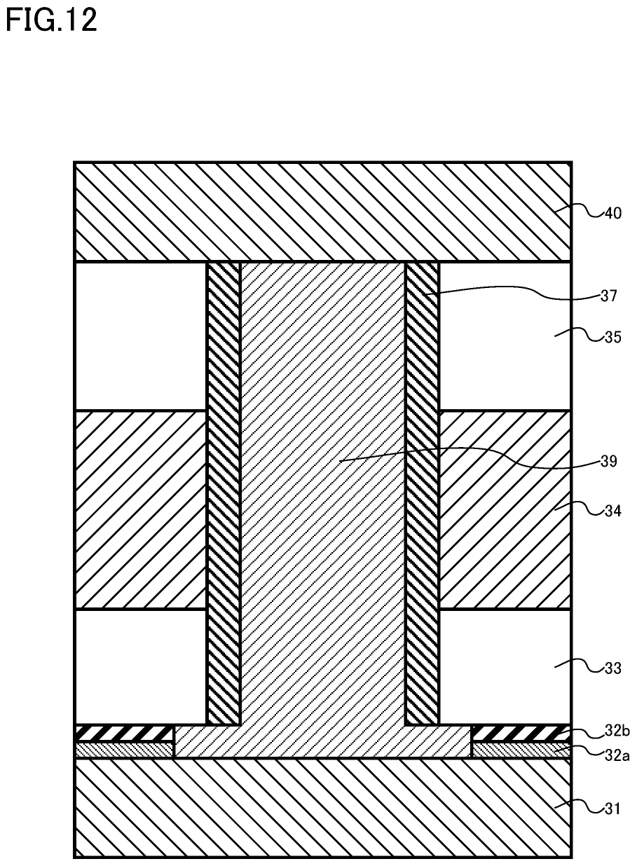

Then, a second indium tin oxide film 40 is formed (FIG. 12). The second indium tin oxide film 40 is formed by using, for example, a CVD method. A part of the second indium tin oxide film 40 finally becomes the upper electrode 14.

By the manufacturing method described above, the transistor 100 shown in FIGS. 1 to 4 is manufactured.

Next, the function and effect of the semiconductor device according to the first embodiment will be described.

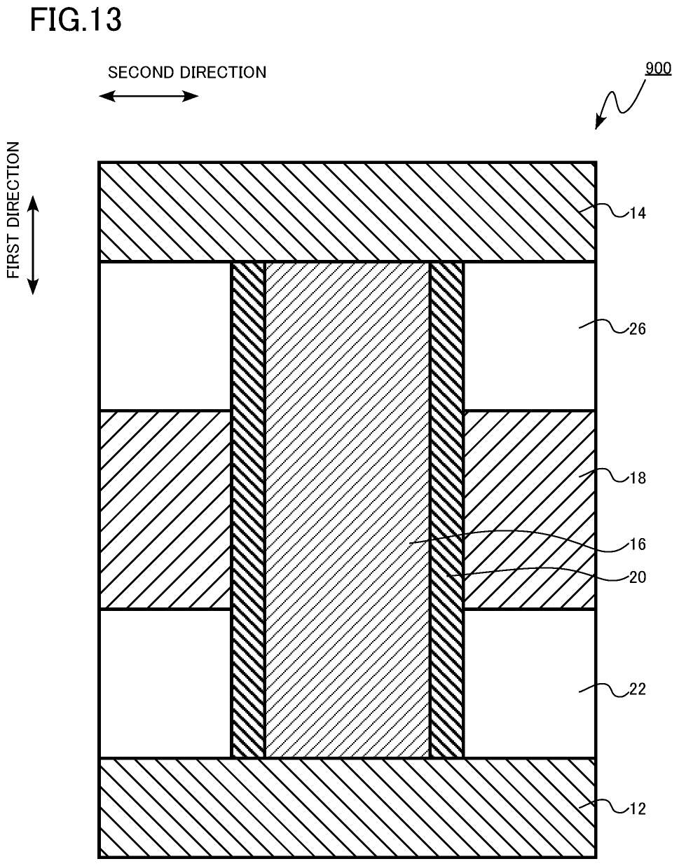

FIG. 13 is a schematic cross-sectional view of a semiconductor device according to a comparative example. FIG. 13 is a diagram corresponding to FIG. 1 of the first embodiment.

The semiconductor device according to the comparative example is a transistor 900. The transistor 900 according to the comparative example is different from the transistor 100 according to the first embodiment in that the transistor 900 does not include the protective layer 24 and the gate insulating layer 20 is in contact with the lower electrode 12.

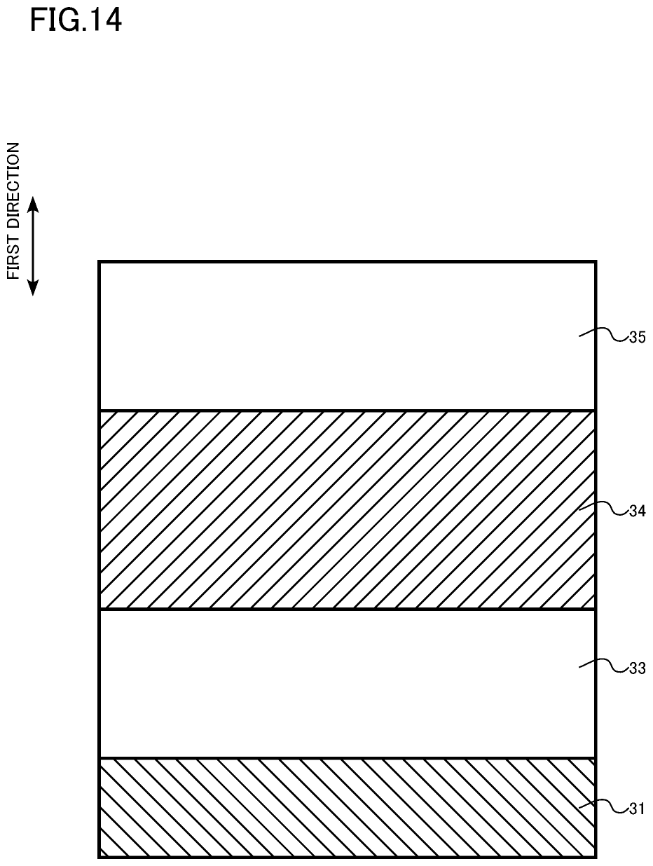

FIGS. 14 to 20 are schematic cross-sectional views showing an example of a method for manufacturing the semiconductor device according to the comparative example. FIGS. 14 to 20 each show a cross section corresponding to FIG. 13. FIGS. 14 to 20 are diagrams showing an example of a method for manufacturing the transistor 900.

Hereinafter, as in the first embodiment, a case where the lower electrode 12 is an indium tin oxide layer, the upper electrode 14 is an indium tin oxide layer, the oxide semiconductor layer 16 is an indium gallium zinc oxide layer, the gate electrode 18 is a tungsten layer, the gate insulating layer 20 is a silicon oxide layer, the lower insulating layer 22 is a silicon oxide layer, and the upper insulating layer 26 is a silicon oxide layer will be described as an example.

First, a first indium tin oxide film 31, a first silicon oxide film 33, a tungsten film 34, and a second silicon oxide film 35 are stacked on a substrate (not shown) in this order in the first direction (FIG. 14). The first indium tin oxide film 31, the first silicon oxide film 33, the tungsten film 34, and the second silicon oxide film 35 are formed by using, for example, a CVD method.

A part of the first indium tin oxide film 31 finally becomes the lower electrode 12. A part of the first silicon oxide film 33 finally becomes the lower insulating layer 22. A part of the tungsten film 34 finally becomes the gate electrode 18. A part of the second silicon oxide film 35 finally becomes the upper insulating layer 26.

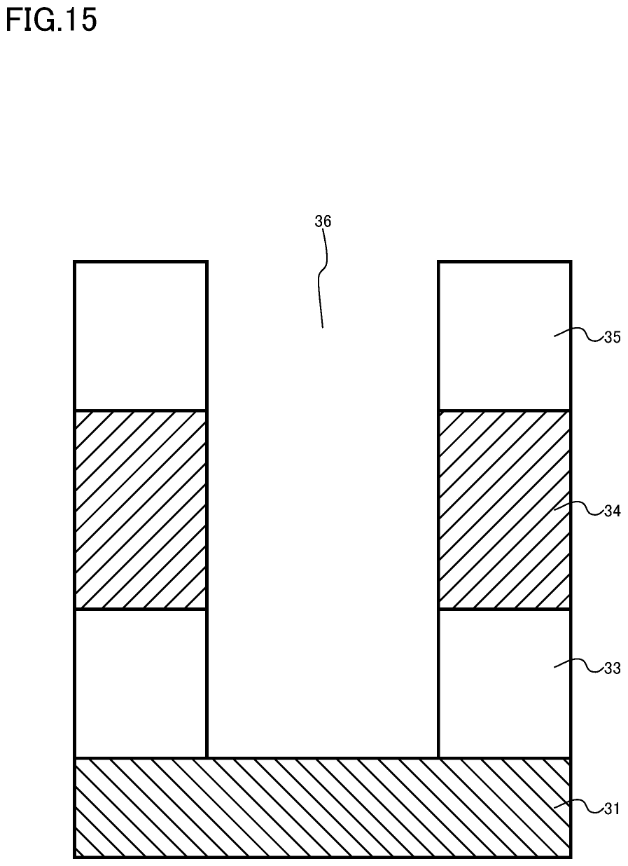

Then, an opening 36 that passes through the tungsten film 34 and the first silicon oxide film 33 and reaches the first indium tin oxide film 31 is formed from the surface of the second silicon oxide film 35 (FIG. 15). The opening 36 is formed by using, for example, a lithography method and an RIE method.

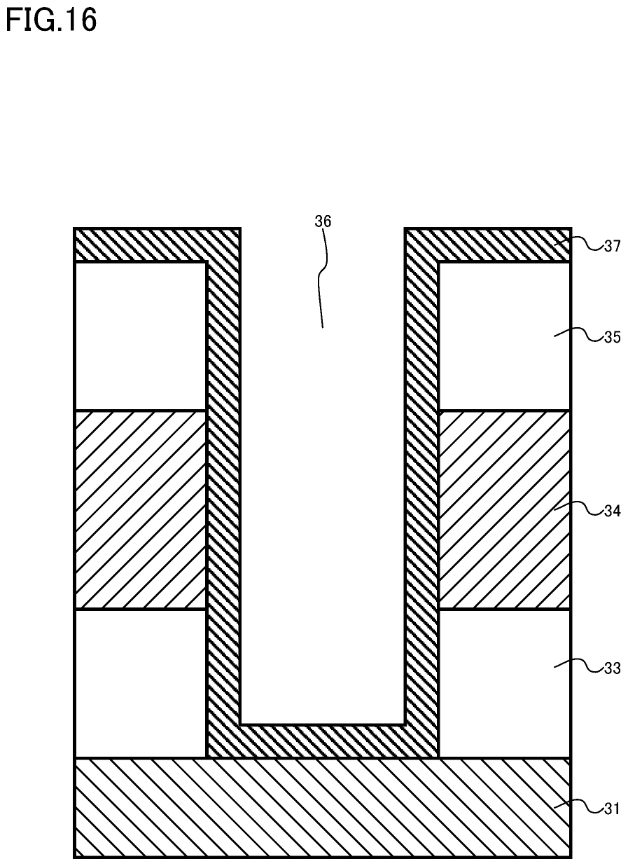

Then, a third silicon oxide film 37 is formed inside the opening 36 (FIG. 16). The third silicon oxide film 37 is formed by using, for example, a CVD method. A part of the third silicon oxide film 37 finally becomes the gate insulating layer 20.

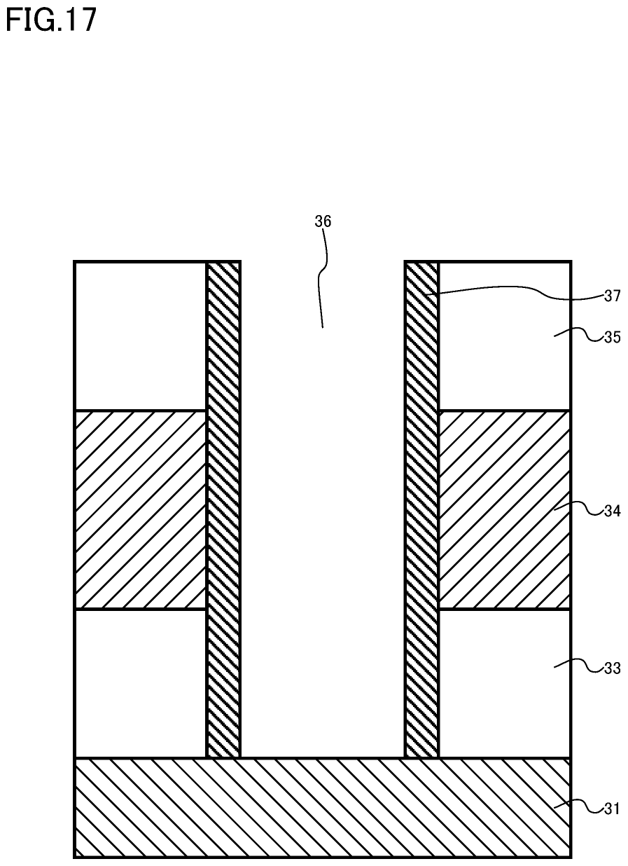

Then, the third silicon oxide film 37 at the bottom of the opening 36 is etched to expose the first indium tin oxide film 31 (FIG. 17). The third silicon oxide film 37 is etched by using, for example, an RIE method.

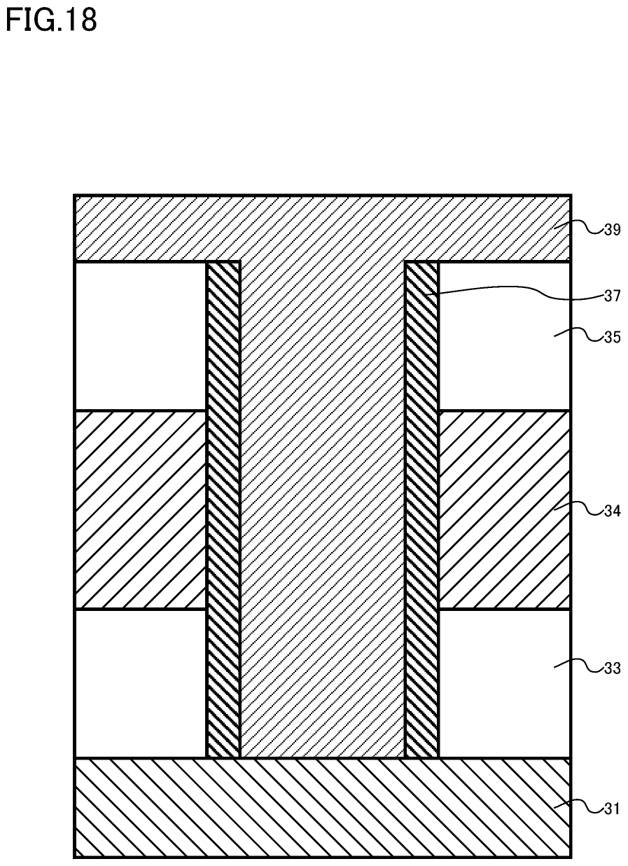

Then, an indium gallium zinc oxide film 39 is buried in the opening 36 (FIG. 18). A part of the indium gallium zinc oxide film 39 becomes the oxide semiconductor layer 16. The indium gallium zinc oxide film 39 is formed by using, for example, a CVD method.

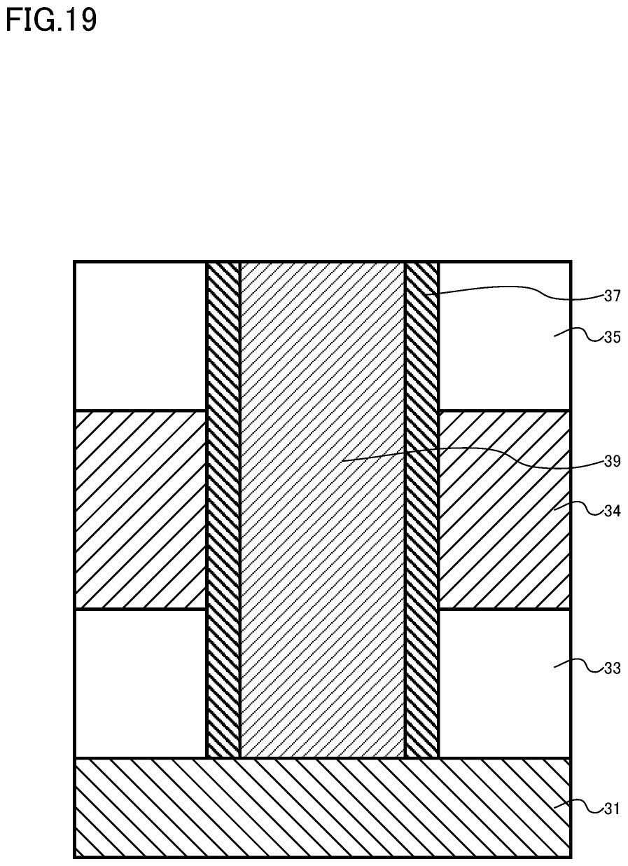

Then, an upper portion of the indium gallium zinc oxide film 39 is removed to expose the surface of the second silicon oxide film 35 (FIG. 19). For example, the indium gallium zinc oxide film 39 is removed by etching using an RIE method.

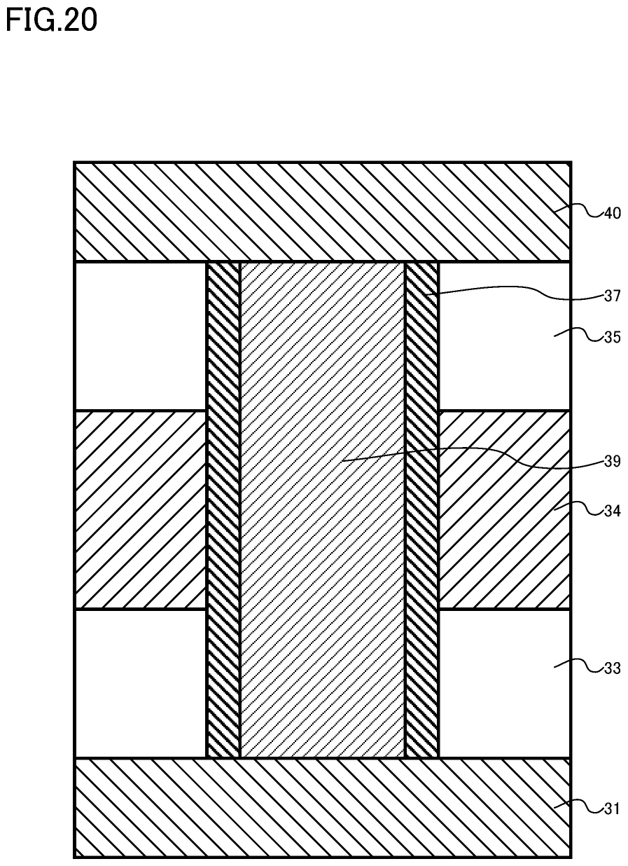

Then, a second indium tin oxide film 40 is formed (FIG. 20). The second indium tin oxide film 40 is formed by using, for example, a CVD method. A part of the second indium tin oxide film 40 finally becomes the upper electrode 14.

By the manufacturing method described above, the transistor 900 shown in FIG. 13 is manufactured.

In manufacturing the transistor 900 according to the comparative example, when forming the opening 36, the surface of the first indium tin oxide film 31 is exposed to etching. For example, the impact of ions causes etching damage to the surface of the first indium tin oxide film 31. In addition, in manufacturing the transistor 900 according to the comparative example, when etching the third silicon oxide film 37 at the bottom of the opening 36, the surface of the first indium tin oxide film 31 is exposed to etching. In this case as well, etching damage occurs on the surface of the first indium tin oxide film 31 due to the impact of ions, for example.

Due to etching damage occurring on the surface of the first indium tin oxide film 31, for example, the contact resistance between the first indium tin oxide film 31 and the indium gallium zinc oxide film 39 increases. In other words, the contact resistance between the lower electrode 12 and the oxide semiconductor layer 16 increases. The higher the contact resistance between the lower electrode 12 and the oxide semiconductor layer 16, the higher the on-resistance of the transistor 900, which is not desirable.

In addition, in manufacturing the transistor 900 according to the comparative example, when forming the third silicon oxide film 37 that becomes the gate insulating layer 20, the surface of the first indium tin oxide film 31 is exposed. For this reason, depending on the conditions for forming the third silicon oxide film 37, the surface of the first indium tin oxide film 31 may be damaged. Therefore, the on-resistance of the transistor 900 increases, which is not desirable.

On the other hand, the transistor 100 according to the first embodiment includes the protective layer 24. Therefore, when forming the opening 36, the surface of the first indium tin oxide film 31 is not exposed to etching. In addition, when etching the third silicon oxide film 37 at the bottom of the opening 36, the surface of the first indium tin oxide film 31 is not exposed to etching. Therefore, no etching damage occurs on the surface of the first indium tin oxide film 31.

In addition, when forming the third silicon oxide film 37 that becomes the gate insulating layer 20, the surface of the first indium tin oxide film 31 is covered with the protective layer 24. Therefore, damage due to the formation of the third silicon oxide film 37 does not occur. As a result, the on-resistance of the transistor 100 is reduced compared with the transistor 900 according to the comparative example.

Since the chemical composition of the protective layer 24 is different from that of the lower insulating layer 22, for example, when forming the opening 36, it is possible to provide a difference in etching rate between a film that finally becomes the protective layer 24 and a film that finally becomes the lower insulating layer 22. Therefore, when forming the opening 36, exposure of the surface of the first indium tin oxide film 31 can be suppressed.

The metal region 24y in the upper portion of the protective layer 24 contains metal. Therefore, it is easy to provide a difference in etching rate between a film that finally becomes the protective layer 24 and a film that finally becomes the lower insulating layer 22.

In addition, the protective layer 24 includes the metal oxide region 24x between the metal region 24y and the lower electrode 12. The inclusion of the metal oxide region 24x improves the adhesion between the lower electrode 12 and the protective layer 24, especially when the surface of the lower electrode 12 is formed of conductive oxide. Therefore, for example, the peeling of the protective layer 24 from the lower electrode 12 can be suppressed.

The first metal element contained in the metal oxide region 24x and the second metal element contained in the metal region 24y are preferably the same element. Since the first metal element and the second metal element are the same element, for example, the adhesion between the metal oxide region 24x and the metal region 24y is improved. Therefore, for example, the peeling of the metal region 24y from the metal oxide region 24x can be suppressed.

In addition, in manufacturing the transistor 100 according to the first embodiment, when etching the titanium nitride film 32b and the titanium oxide film 32a at the bottom of the opening 36, the surface of the first indium tin oxide film 31 is exposed to etching. However, by using, for example, a wet etching method, it is possible to suppress the occurrence of etching damage on the surface of the first indium tin oxide film 31.

The first metal element contained in the metal oxide region 24x of the protective layer 24 is preferably at least one of titanium (Ti) and tungsten (W). It is preferable that the metal oxide region 24x contains titanium oxide or tungsten oxide.

Titanium oxide and tungsten oxide can be etched by a wet etching method using a solution containing hydrogen peroxide as a main component.

The second metal element contained in the metal region 24y of the protective layer 24 is preferably at least one of titanium (Ti) and tungsten (W). It is preferable that the metal region 24y contains metal containing titanium (Ti) or metal containing tungsten (W). It is preferable that the metal region 24y contains at least one metal selected from a group consisting of titanium, titanium nitride, titanium oxynitride, titanium carbide, tungsten, tungsten nitride, tungsten oxynitride, tungsten carbide, titanium tungsten, molybdenum tungsten, and tantalum tungsten.

Metals containing titanium (Ti) and metals containing tungsten (W) can be etched by a wet etching method using a solution containing hydrogen peroxide as a main component.

A solution containing hydrogen peroxide as a main component is a neutral or weakly acidic solution. Therefore, when forming the recess 38 as shown in FIG. 9, the etching rates of the films that finally become the lower electrode 12, the lower insulating layer 22, and the gate insulating layer 20 can be extremely reduced.

For example, the etching rates of the first indium tin oxide film 31, the first silicon oxide film 33, and the third silicon oxide film 37 are extremely reduced. In other words, when etching the titanium nitride film 32b and the titanium oxide film 32a, it is extremely easy to provide a difference in etching rate between the titanium nitride film 32b and the titanium oxide film 32a and the first indium tin oxide film 31, the first silicon oxide film 33, and the third silicon oxide film 37. Therefore, it becomes easy to form the recess 38.

In the transistor 100 according to the first embodiment, the first minimum distance (d1 in FIG. 1) between the third portion 24a and the fourth portion 24b is larger than the second minimum distance (d2 in FIG. 1) between the fifth portion 20a and the sixth portion 20b. Therefore, for example, the contact area between the lower electrode 12 and the oxide semiconductor layer 16 increases compared with the transistor 900 according to the comparative example. Therefore, the contact resistance between the lower electrode 12 and the oxide semiconductor layer 16 becomes low. As a result, the on-resistance of the transistor 100 is reduced.

From the viewpoint of increasing the contact area between the lower electrode 12 and the oxide semiconductor layer 16 and lowering the contact resistance between the lower electrode 12 and the oxide semiconductor layer 16, it is preferable that the first minimum distance d1 is larger than the third minimum distance (d3 in FIG. 1) between the first portion 22a and the second portion 22b. In addition, from the viewpoint of reducing the contact resistance between the lower electrode 12 and the oxide semiconductor layer 16, it is preferable that the first minimum distance d1 is larger than the maximum distance (d4 in FIG. 1) between the ninth portion 20c and the tenth portion 20d.

### Modification Example

A semiconductor device according to a modification example of the first embodiment is different from the semiconductor device according to the first embodiment in that the first minimum distance between the third portion and the fourth portion is equal to the second minimum distance between the fifth portion and the sixth portion.

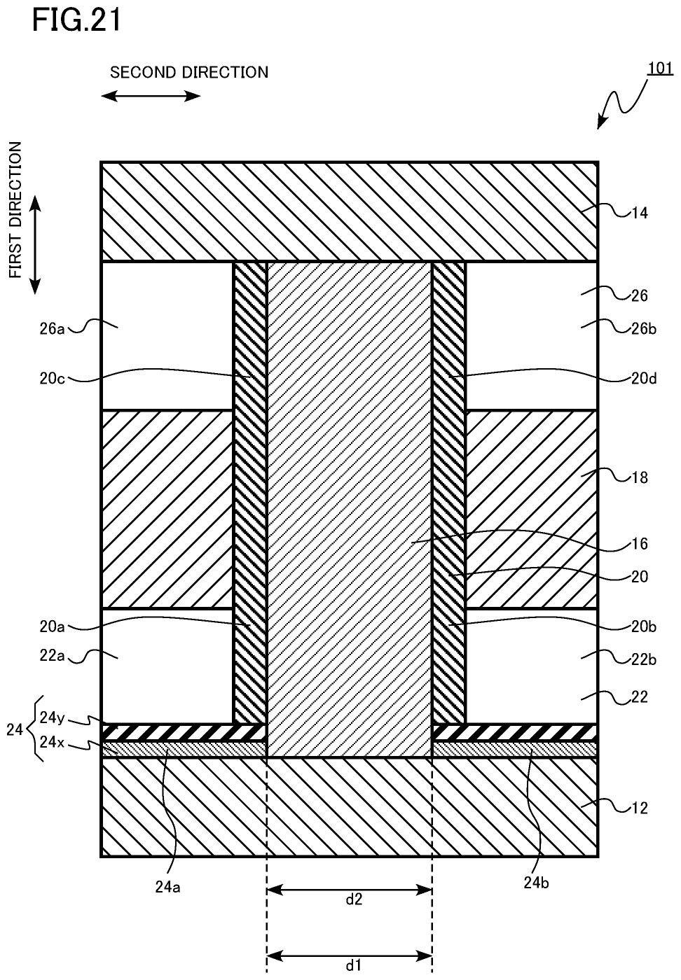

FIG. 21 is a schematic cross-sectional view of the semiconductor device according to the modification example of the first embodiment. The semiconductor device according to the modification example of the first embodiment is a transistor 101. FIG. 21 is a diagram corresponding to FIG. 1 of the first embodiment.

As shown in FIG. 21, the first minimum distance (d1 in FIG. 21) between the third portion 24a and the fourth portion 24b is equal to the second minimum distance (d2 in FIG. 21) between the fifth portion 20a and the sixth portion 20b.

The transistor 101 according to the modification example of the first embodiment includes the protective layer 24, so that the on-resistance is reduced similarly to the transistor 100 according to the first embodiment.

As described above, according to the first embodiment and its modification examples, it is possible to realize a semiconductor device with reduced on-resistance and excellent transistor characteristics.

### Second Embodiment

A semiconductor device according to a second embodiment is different from the semiconductor device according to the first embodiment in that the second minimum distance between the fifth portion and the sixth portion is smaller than the maximum distance between the ninth portion and the tenth portion. Hereinafter, the description of a part of the content overlapping the first embodiment may be omitted.

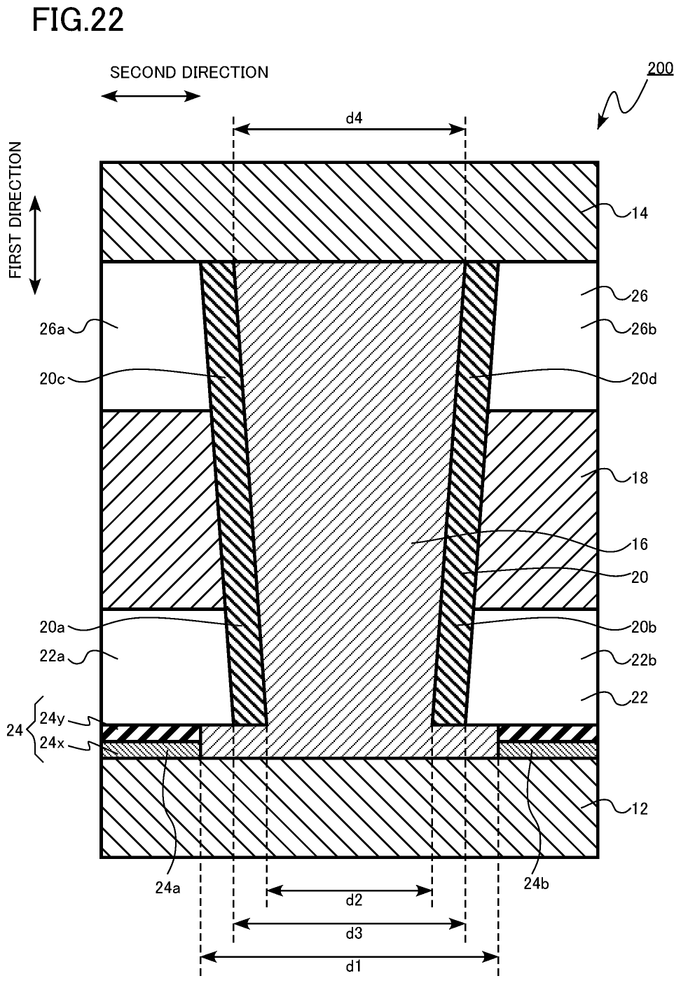

FIG. 22 is a schematic cross-sectional view of the semiconductor device according to the second embodiment. The semiconductor device according to the second embodiment is a transistor 200.

The transistor 200 is an oxide semiconductor transistor in which a channel is formed in an oxide semiconductor. In the transistor 200, a gate electrode is provided so as to surround an oxide semiconductor layer in which a channel is formed. The transistor 200 is a so-called SGT. The transistor 200 is a so-called vertical transistor.

The transistor 200 includes a lower electrode 12, an upper electrode 14, an oxide semiconductor layer 16, a gate electrode 18, a gate insulating layer 20, a lower insulating layer 22, a protective layer 24, and an upper insulating layer 26. The lower insulating layer 22 includes a first portion 22a and a second portion 22b. The protective layer 24 includes a third portion 24a and a fourth portion 24b. The gate insulating layer 20 includes a fifth portion 20a, a sixth portion 20b, a ninth portion 20c, and a tenth portion 20d. The upper insulating layer 26 includes a seventh portion 26a and an eighth portion 26b.

The lower electrode 12 is an example of the first electrode. The upper electrode 14 is an example of the second electrode. The lower insulating layer 22 is an example of the first insulating layer. The protective layer 24 is an example of an intermediate layer. The upper insulating layer 26 is an example of the second insulating layer.

The second minimum distance (d2 in FIG. 22) between the fifth portion 20a and the sixth portion 20b is smaller than the maximum distance (d4 in FIG. 22) between the ninth portion 20c and the tenth portion 20d. In the first cross section parallel to the first direction, the side surface of the oxide semiconductor layer 16 has a forward tapered shape.

For example, the first minimum distance (d1 in FIG. 22) between the third portion 24a and the fourth portion 24b is larger than the second minimum distance (d2 in FIG. 22) between the fifth portion 20a and the sixth portion 20b. In addition, for example, the first minimum distance d1 is larger than the third minimum distance (d3 in FIG. 22) between the first portion 22a and the second portion 22b. In addition, for example, the first minimum distance d1 is larger than the maximum distance (d4 in FIG. 22) between the ninth portion 20c and the tenth portion 20d.

The transistor 200 according to the second embodiment includes the protective layer 24, so that the on-resistance is reduced similarly to the transistor 100 according to the first embodiment.

### Modification Example

A semiconductor device according to a modification example of the second embodiment is different from the semiconductor device according to the second embodiment in that the semiconductor device according to the modification example of the second embodiment further includes a fourth insulating layer surrounded by an oxide semiconductor layer.

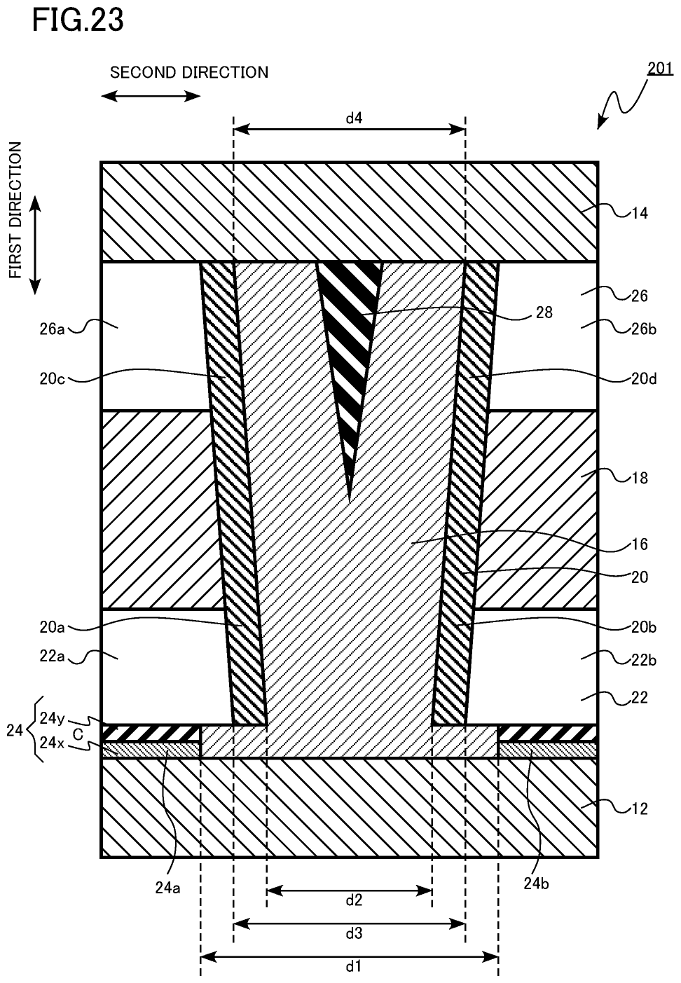

FIG. 23 is a schematic cross-sectional view of the semiconductor device according to the modification example of the second embodiment. The semiconductor device according to the modification example of the second embodiment is a transistor 201. FIG. 23 is a diagram corresponding to FIG. 22 of the second embodiment.

The transistor 201 includes a core insulating layer 28. The core insulating layer 28 is an example of the fourth insulating layer.

The core insulating layer 28 is surrounded by the oxide semiconductor layer 16 in a cross section perpendicular to the first direction. For example, the core insulating layer 28 includes an upper insulating layer 26 and is surrounded by the oxide semiconductor layer 16 in a cross section perpendicular to the first direction.

The core insulating layer 28 extends in the first direction. The core insulating layer 28 is in contact with, for example, the upper electrode 14.

The core insulating layer 28 is an insulator. The core insulating layer 28 is, for example, an oxide, a nitride, or an oxynitride. The core insulating layer 28 contains, for example, silicon (Si) and oxygen (O). The core insulating layer 28 contains, for example, silicon oxide. The core insulating layer 28 is, for example, a silicon oxide layer.

The transistor 201 according to the modification example of the second embodiment includes the protective layer 24, so that the on-resistance is reduced similarly to the transistor 200 according to the second embodiment.

As described above, according to the second embodiment and its modification examples, it is possible to realize a semiconductor device with reduced on-resistance and excellent transistor characteristics.

### Third Embodiment

A semiconductor device according to a third embodiment includes: a first electrode; a second electrode; an oxide semiconductor layer provided between the first electrode and the second electrode; a gate electrode surrounding the oxide semiconductor layer; a gate insulating layer provided between the gate electrode and the oxide semiconductor layer and spaced from the first electrode; a first insulating layer provided between the first electrode and the gate electrode, the gate insulating layer being provided between the first insulating layer and the oxide semiconductor layer; and an intermediate layer provided between the first electrode and the first insulating layer, containing at least one of titanium (Ti) and tungsten (W), and having a different chemical composition from the first electrode. The semiconductor device according to the third embodiment is different from the semiconductor device according to the first embodiment in that the intermediate layer is not divided into two regions. Hereinafter, the description of a part of the content overlapping the first embodiment may be omitted.

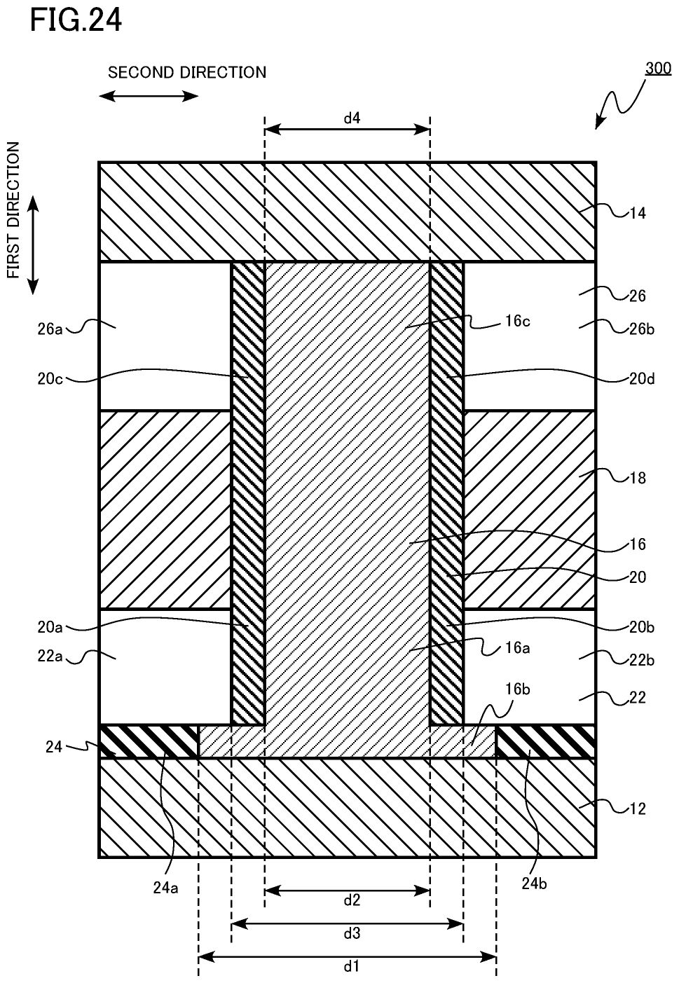

FIG. 24 is a schematic cross-sectional view of the semiconductor device according to the third embodiment. FIG. 24 is a diagram corresponding to FIG. 1 of the first embodiment. In FIG. 24, the vertical direction is referred to as a first direction. In FIG. 24, the horizontal direction is referred to as a second direction. The second direction is perpendicular to the first direction.

The semiconductor device according to the third embodiment is a transistor 300. The transistor 300 is an oxide semiconductor transistor in which a channel is formed in an oxide semiconductor. In the transistor 300, a gate electrode is provided so as to surround an oxide semiconductor layer in which a channel is formed. The transistor 300 is a so-called surrounding gate transistor (SGT). The transistor 300 is a so-called vertical transistor.

The transistor 300 includes a lower electrode 12, an upper electrode 14, an oxide semiconductor layer 16, a gate electrode 18, a gate insulating layer 20, a lower insulating layer 22, a protective layer 24, and an upper insulating layer 26. The oxide semiconductor layer 16 includes a first sub-region 16a, a second sub-region 16b, and a third sub-region 16c. The lower insulating layer 22 includes a first portion 22a and a second portion 22b. The gate insulating layer 20 includes a fifth portion 20a, a sixth portion 20b, a ninth portion 20c, and a tenth portion 20d. The upper insulating layer 26 includes a seventh portion 26a and an eighth portion 26b.

The lower electrode 12 is an example of the first electrode. The upper electrode 14 is an example of the second electrode. The lower insulating layer 22 is an example of the first insulating layer. The protective layer 24 is an example of an intermediate layer. Upper insulating layer 26 is an example of the second insulating layer.

The protective layer 24 is provided on the lower electrode 12. The protective layer 24 is provided between the lower electrode 12 and the lower insulating layer 22. The protective layer 24 is in contact with, for example, the lower electrode 12. The protective layer 24 is in contact with, for example, the lower insulating layer 22.

The protective layer 24 surrounds the second sub-region 16b of the oxide semiconductor layer 16. The protective layer 24 is in contact with, for example, the second sub-region 16b of the oxide semiconductor layer 16.

The protective layer 24 has a function of suppressing etching of the lower electrode 12 when forming a contact structure between the lower electrode 12 and the oxide semiconductor layer 16.

The protective layer 24 has a different chemical composition from the lower electrode 12, the lower insulating layer 22, and the oxide semiconductor layer 16.

The protective layer 24 contains at least one of titanium (Ti) and tungsten (W). The protective layer 24 is, for example, a metal oxide or a metal.

The protective layer 24 contains, for example, at least one substance selected from a group consisting of titanium, titanium oxide, titanium nitride, titanium oxynitride, titanium carbide, tungsten, tungsten oxide, tungsten nitride, tungsten oxynitride, tungsten carbide, tungsten titanium, tungsten molybdenum, and tungsten tantalum. The protective layer 24 is, for example, a titanium layer, a titanium oxide layer, a titanium nitride layer, a titanium oxynitride layer, a titanium carbide layer, a tungsten layer, a tungsten oxide layer, a tungsten nitride layer, a tungsten oxynitride layer, a tungsten carbide layer, a titanium tungsten layer, a molybdenum tungsten layer, and a tantalum tungsten layer.

The thickness of the protective layer 24 in the first direction is smaller than the thickness of the lower insulating layer 22 in the first direction, for example. The thickness of the protective layer 24 in the first direction is, for example, equal to or less than 30% of the thickness of the lower insulating layer 22 in the first direction.

According to the transistor 300 according to the third embodiment, the on-resistance of the transistor 300 is reduced due to the same function and effect as in the transistor 100 according to the first embodiment.

A substance containing titanium (Ti) and a substance containing tungsten (W) can be etched by a wet etching method using a solution containing hydrogen peroxide as a main component. For example, metal oxides containing titanium (Ti), metals containing titanium (Ti), metal oxides containing tungsten (W), and metals containing tungsten (W) can be etched by a wet etching method using a solution containing hydrogen peroxide as a main component.

A solution containing hydrogen peroxide as a main component is a neutral or weakly acidic solution. Therefore, when forming the recess 38 as shown in FIG. 9, if a solution containing hydrogen peroxide as a main component is used as an etching solution, the etching rates of the films that finally become the lower electrode 12, the lower insulating layer 22, and the gate insulating layer 20 can be extremely reduced.

For example, the etching rates of the first indium tin oxide film 31, the first silicon oxide film 33, and the third silicon oxide film 37 are extremely reduced. In other words, when etching the film that becomes the protective layer 24, it is extremely easy to provide a difference in etching rate between the titanium nitride film 32b and the titanium oxide film 32a and the first indium tin oxide film 31, the first silicon oxide film 33, and the third silicon oxide film 37. Therefore, according to the transistor 300 according to the third embodiment, the recess 38 can be easily formed.

### Fourth Embodiment

A semiconductor memory device according to a fourth embodiment includes the semiconductor device according to the first embodiment and a capacitor electrically connected to the first electrode or the second electrode.

The semiconductor memory device according to the fourth embodiment is a semiconductor memory 400. The semiconductor memory device according to the fourth embodiment is a DRAM. In the semiconductor memory 400, the transistor 100 according to the first embodiment is used as a switching transistor of a memory cell of a DRAM.

Hereinafter, the description of a part of the content overlapping the first embodiment will be omitted.

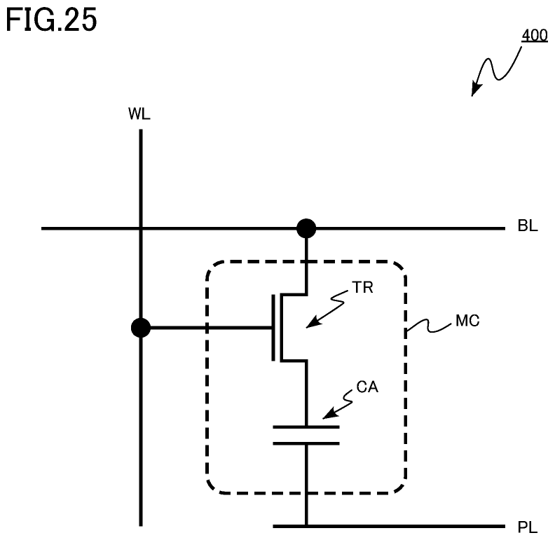

FIG. 25 is an equivalent circuit diagram of the semiconductor memory device according to the fourth embodiment. FIG. 25 illustrates a case where one memory cell MC is provided. However, for example, a plurality of memory cells MC may be provided in an array.

The semiconductor memory 400 includes the memory cell MC, a word line WL, a bit line BL, and a plate line PL. The memory cell MC includes a switching transistor TR and a capacitor CA. In FIG. 25, the area surrounded by the broken line is the memory cell MC.

The word line WL is electrically connected to the gate electrode of the switching transistor TR. The bit line BL is electrically connected to one of the source electrode and the drain electrode of the switching transistor TR. One electrode of the capacitor CA is electrically connected to the other one of the source electrode and the drain electrode of the switching transistor TR. The other electrode of the capacitor CA is connected to the plate line PL.

The memory cell MC stores data by storing charges in the capacitor CA. Data is written and read by turning on the switching transistor TR.

For example, data is written into the memory cell MC by turning on the switching transistor TR in a state in which a desired voltage is applied to the bit line BL.

In addition, for example, a voltage change in the bit line BL according to the amount of charge stored in the capacitor is detected by turning on the switching transistor TR, thereby reading the data of the memory cell MC.

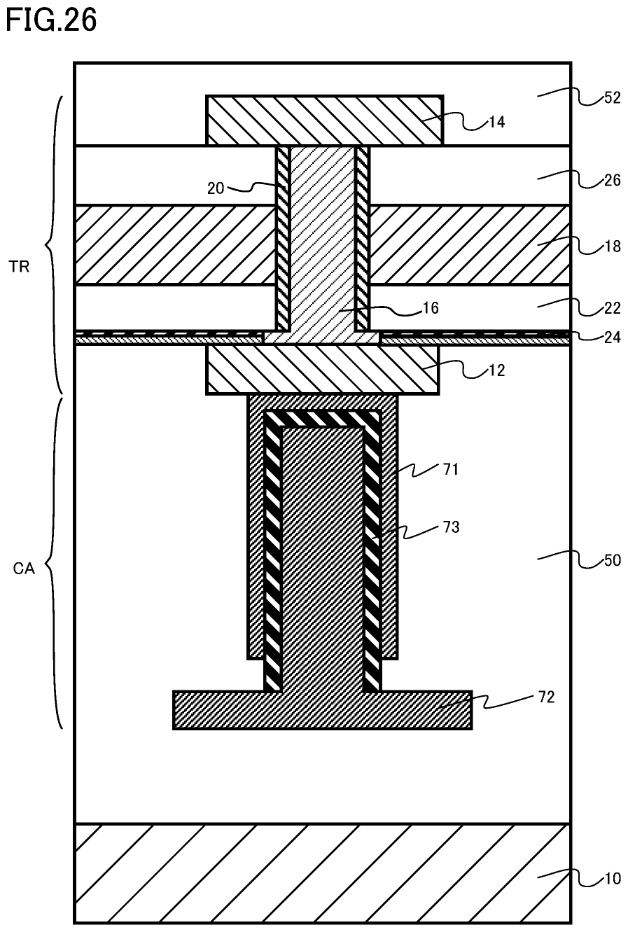

FIG. 26 is a schematic cross-sectional view of the semiconductor memory device according to the fourth embodiment. FIG. 26 shows a cross section of the memory cell MC of the semiconductor memory 400.

The semiconductor memory 400 includes a silicon substrate 10, the switching transistor TR, the capacitor CA, a first interlayer insulating layer 50, and a second interlayer insulating layer 52.

The switching transistor TR includes a lower electrode 12, an upper electrode 14, an oxide semiconductor layer 16, a gate electrode 18, a gate insulating layer 20, a lower insulating layer 22, a protective layer 24, and an upper insulating layer 26.

The switching transistor TR has a structure similar to that of the transistor 100 according to the first embodiment.

The capacitor CA is provided between the silicon substrate 10 and the switching transistor TR. The capacitor CA is provided between the silicon substrate 10 and the lower electrode 12. The capacitor CA is electrically connected to the lower electrode 12.

The capacitor CA includes a cell electrode 71, a plate electrode 72, and a capacitor insulating film 73. The cell electrode 71 is electrically connected to the lower electrode 12. The cell electrode 71 is in contact with, for example, the lower electrode 12.

Each of the cell electrode 71 and the plate electrode 72 is, for example, a titanium nitride. The capacitor insulating film 73 has, for example, a stacked structure of zirconium oxide, aluminum oxide, and zirconium oxide.

The gate electrode 18 is electrically connected to, for example, the word line WL (not shown). The upper electrode 14 is electrically connected to, for example, the bit line BL (not shown). The plate electrode 72 is connected to, for example, the plate line PL (not shown).

In the semiconductor memory 400, an oxide semiconductor transistor having a very small channel leakage current during off operation is applied as the switching transistor TR. Therefore, a DRAM having an excellent charge storage characteristic is realized.

In addition, the switching transistor TR of the semiconductor memory 400 has a small on-resistance. Therefore, for example, the write speed or read speed of the memory cell MC increases. Therefore, the operating characteristics of the semiconductor memory 400 are improved.

In the fourth embodiment, a semiconductor memory to which the transistor according to the first embodiment is applied has been described as an example. However, the semiconductor memory of embodiments may be a semiconductor memory to which the transistor according to the second embodiment or the third embodiment is applied.

In the fourth embodiment, a semiconductor memory in which a cell electrode is electrically connected to the lower electrode 12 has been described as an example. However, the semiconductor memory of embodiments may be a semiconductor memory in which a cell electrode is electrically connected to the upper electrode 14.

The capacitor CA may have a structure provided on the switching transistor TR. A structure in which the switching transistor TR is provided between the silicon substrate 10 and the capacitor CA may be used.

While certain embodiments have been described, these embodiments have been presented by way of example only, and are not intended to limit the scope of the inventions. Indeed, the semiconductor device and the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode;
a second electrode;
an oxide semiconductor layer provided between the first electrode and the second electrode;
a gate electrode surrounding the oxide semiconductor layer;
a gate insulating layer provided between the gate electrode and the oxide semiconductor layer and spaced from the first electrode;
a first insulating layer provided between the first electrode and the gate electrode, the gate insulating layer being provided between the first insulating layer and the oxide semiconductor layer; and
an intermediate layer provided between the first electrode and the first insulating layer, including a first region and a second region provided between the first region and the first insulating layer, and the intermediate layer having a different chemical composition from the first electrode,
wherein the first region contains a first metal element and oxygen (O),
the second region contains a second metal element, and
an oxygen concentration in the second region is lower than an oxygen concentration in the first region.

2. The semiconductor device according to claim 1,
wherein the first insulating layer surrounds a part of the oxide semiconductor layer, and the intermediate layer surrounds another part of the oxide semiconductor layer.

3. The semiconductor device according to claim 2,
wherein the oxide semiconductor layer is in contact with the first electrode.

4. The semiconductor device according to claim 1,
wherein, in a first cross section parallel to a first direction from the first electrode toward the second electrode and including the oxide semiconductor layer, the first insulating layer, the intermediate layer, and the gate insulating layer,
the first insulating layer includes a first portion and a second portion, the intermediate layer includes a third portion and a fourth portion, and the gate insulating layer includes a fifth portion and a sixth portion,
the oxide semiconductor layer is provided between the first portion and the second portion, the oxide semiconductor layer is provided between the third portion and the fourth portion, the fifth portion is provided between the first portion and the oxide semiconductor layer, and the sixth portion is provided between the second portion and the oxide semiconductor layer, and
a first minimum distance between the third portion and the fourth portion is larger than a second minimum distance between the fifth portion and the sixth portion.

5. The semiconductor device according to claim 4,
wherein the first minimum distance is larger than a third minimum distance between the first portion and the second portion.

6. The semiconductor device according to claim 4, further comprising:
a second insulating layer provided between the second electrode and the gate electrode,
wherein the first cross section includes the second insulating layer,
the second insulating layer includes a seventh portion and an eighth portion, and the gate insulating layer further includes a ninth portion and a tenth portion,
the oxide semiconductor layer is provided between the seventh portion and the eighth portion, the ninth portion is provided between the seventh portion and the oxide semiconductor layer, and the tenth portion is provided between the eighth portion and the oxide semiconductor layer, and
the first minimum distance is larger than a maximum distance between the ninth portion and the tenth portion.

7. The semiconductor device according to claim 4, further comprising:
a second insulating layer provided between the second electrode and the gate electrode,
wherein the first cross section includes the second insulating layer,
the second insulating layer includes a seventh portion and an eighth portion, and the gate insulating layer further includes a ninth portion and a tenth portion,
the oxide semiconductor layer is provided between the seventh portion and the eighth portion, the ninth portion is provided between the seventh portion and the oxide semiconductor layer, and the tenth portion is provided between the eighth portion and the oxide semiconductor layer, and
the second minimum distance is smaller than a maximum distance between the ninth portion and the tenth portion.

8. The semiconductor device according to claim 1,
wherein a thickness of the intermediate layer in a first direction from the first electrode toward the second electrode is smaller than a thickness of the first insulating layer in the first direction.

9. The semiconductor device according to claim 1,
wherein the gate insulating layer is in contact with the second electrode.

10. The semiconductor device according to claim 4,
wherein the third portion is in contact with the oxide semiconductor layer, and the fourth portion is in contact with the oxide semiconductor layer.

11. The semiconductor device according to claim 1,
wherein the first metal element and the second metal element are same element.

12. The semiconductor device according to claim 1,
wherein the first region contains oxide of the first metal element, and the second region contains metal containing the second metal element.

13. The semiconductor device according to claim 1,
wherein the first metal element is at least one of titanium (Ti) and tungsten (W), and the second metal element is at least one of titanium (Ti) and tungsten (W).

14. The semiconductor device according to claim 1,
wherein the first electrode contains indium (In), tin (Sn), and oxygen (O).

15. A semiconductor memory device, comprising:
the semiconductor device according to claim 1; and
a capacitor electrically connected to the first electrode or the second electrode.

16. A semiconductor device, comprising:
a first electrode;
a second electrode;
an oxide semiconductor layer provided between the first electrode and the second electrode;
a gate electrode surrounding the oxide semiconductor layer;
a gate insulating layer provided between the gate electrode and the oxide semiconductor layer and spaced from the first electrode;
a first insulating layer provided between the first electrode and the gate electrode, the gate insulating layer being provided between the first insulating layer and the oxide semiconductor layer; and
an intermediate layer provided between the first electrode and the first insulating layer, containing at least one of titanium (Ti) and tungsten (W), and having a different chemical composition from the first electrode.

17. The semiconductor device according to claim 16,
wherein the intermediate layer contains at least one substance selected from a group consisting of titanium, titanium oxide, titanium nitride, titanium oxynitride, titanium carbide, tungsten, tungsten oxide, tungsten nitride, tungsten oxynitride, tungsten carbide, titanium tungsten, molybdenum tungsten, and tantalum tungsten.

18. The semiconductor device according to claim 16,
wherein the first insulating layer surrounds a part of the oxide semiconductor layer, and the intermediate layer surrounds another part of the oxide semiconductor layer.

19. The semiconductor device according to claim 18,
wherein the oxide semiconductor layer is in contact with the first electrode.

20. A semiconductor memory device, comprising:
the semiconductor device according to claim 16; and
a capacitor electrically connected to the first electrode or the second electrode.
